(19) United States
(12) Patent Application Publication
(10) Pub. No.: US 2023/0258714 A1
(43) Pub. Date: Aug. 17, 2023

(54) ICG TEST COVERAGE WITH NO TIMING OVERHEAD

(71) Applicant: MediaTek Singapore Pte. Ltd., Singapore (SG)

(72) Inventor: Raghuraman Rajanarayanan, Varthur Hobli (IN)

(73) Assignee: MediaTek Singapore Pte. Ltd., Singapore (SG)

(21) Appl. No.: 17/672,527

(22) Filed: Feb. 15, 2022

(51) Int. Cl. G01R 31/317; H03K 3/037

(52) U.S. Cl. CPC G01R 31/31727; H03K 3/037; H03K 19/20

(57) ABSTRACT

A circuit for testing a fault of an enable net of an integrated clock gating (ICG) cell is provided. The circuit includes a flip flop, wherein an input clock signal of the flip flop is an output of the ICG cell and the flip flop receives an inversion of an output of the flip flop as input data signal. Circuitry for performing a transition fault test is also provided, comprising a first ICG cell coupled to a first flip flop and a second ICG cell coupled to a second flip flop, the first ICG configured to receive a first enable signal and the second ICG cell configured to receive a second enable signal, and wherein the first and second ICG cell are individually controlled so the first and second flip flop are operable to receive a pulse at different times.

### BACKGROUND

Digital circuits may be evaluated for defects through testing. Fault models may be used to model defects. High fault coverage during testing is desirable so that a high percentage of defects can be identified. Structured testing for the logic of digital circuits can be performed using ATPG (Automatic Test Pattern Generation, or Automatic Test Pattern Generator), which tests the circuitry for defects modeled as faults. The most commonly used fault models include stuck-at-0/1 fault models and transition fault models.

### SUMMARY

Some embodiments relate to a circuit for testing a fault of an enable net of an integrated clock gating (ICG) cell, the circuit comprising: a flip flop, wherein an input clock signal of the flip flop is an output of the ICG cell, wherein the flip flop receives an inversion of an output of the flip flop as an input data signal.

Some embodiments relate to a method of testing a fault of an enable net of an integrated clock gating (ICG) cell, the method comprising determining, based on an output of a flip flop coupled to an output of the ICG cell, whether the enable net of the ICG cell has a stuck-at-zero fault.

Some embodiments relate to a method of performing a transition fault test, the method comprising: asserting a first enable signal of a first ICG cell; pulsing, in response to asserting the first enable signal, a first pulse as a clock signal output of a first flip flop; comparing one or more output values of the flip flop to one or more expected values; and determining, based on the comparison, whether or not a transition fault exists.

Some embodiments relate to circuitry configured to perform a transition fault test, the circuitry comprising: a first ICG cell coupled to a first flip flop, wherein the first ICG is configured to receive a first enable signal; and a second ICG cell coupled to a second flip flop, wherein the second ICG cell is configured to receive a second enable signal, wherein the first ICG cell and second ICG cell are individually controlled such that the first and second flip flop are operable to receive a pulse at different times.

The foregoing summary is provided by way of illustration and is not intended to be limiting.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing.

FIG. 1 is an exemplary circuit diagram for which a structured testing tool (e.g., ATPG) fails to detect defects, according to some embodiments.

FIG. 2 is the exemplary circuit diagram of FIG. 1 with added circuitry configured to allow detectability of faults, according to some embodiments.

FIG. 3 is an exemplary diagram of an exemplary circuit diagram for which transition faults can be tested, according to some embodiments.

FIG. 4 is the exemplary circuit diagram of FIG. 3 with added circuitry configured to reduce capture power in transition fault testing, according to some embodiments.

### DETAILED DESCRIPTION

As mentioned above, structured testing for logic may be performed using electronic design automation methods and technologies such as ATPG.

Common fault models include stuck-at-0/1 fault models and transition fault models. Stuck-at-0/1 fault models are fault models used by fault simulators and automatic test pattern generation (ATPG) tools to imitate defects in manufacturing in circuits where a net is shorted to power or ground. For a stuck-at-0/1 fault model, test values (e.g., one or more bits) may be input into the circuit and the output may be read and compared against one or more expected values. If the output values do not equal the expected values, the circuit may have one or more stuck-at-0/1 faults.

Delay fault models, such as transition fault models, can indicate defects that may cause circuits to malfunction when operated at the desired clock rate or higher. These defects thus violate timing specifications. Delay faults can be modeled by modeling defects that affect delays at the inputs or outputs of gates.

For many circuits, the fault coverage of all nets in a circuit is often not complete (i.e., not 100% testable). However, some nets are more important than others, and may benefit from high fault coverage or complete fault coverage. However, electronic design automatic methods and technologies such as ATPG fail to provide coverage for many circuits, including those with integrated clock gating cells (ICGs). While diagnosis of faults is an important part of silicon to production flow, diagnosis capabilities are often restricted to the faults in Q to D path and faults in clock paths are considered ‘detected by implication’ or even worse, ignored.

The inventors have recognized and appreciated that the performance of such systems and operations may be improved by techniques and circuitry configured to allow more complete fault testing of ICGs, for example, by fault testing of enable nets of ICGs. The inventors have also recognized and appreciated that ICGs may be used in transition fault testing. In particular, ICGs may be leveraged to reduce capture power in transition fault testing and may increase efficiency of testing by reducing the number of pulses needed to test the transition timing.

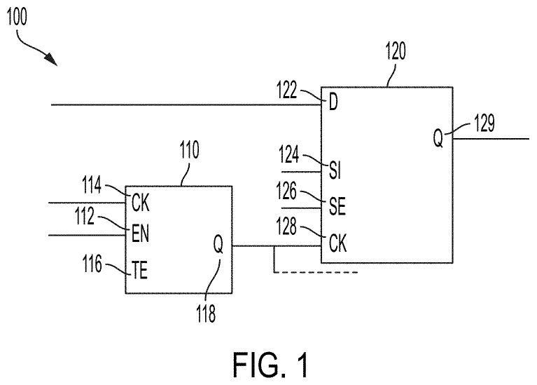

FIG. 1 is an exemplary circuit diagram 100 for which a structured testing tool (e.g., ATPG) fails to detect defects. The circuit 100 includes an ICG 110 and a flip flop 120. The ICG 110 receives inputs including enable signal, EN 112, and clock signal, CK 114. The ICG 110 may also include a test enable signal, TE 116, such that when TE 116 is asserted, the circuit may function in a test mode. The ICG 110 outputs an output signal, Q 118. The flip flop 120 receives inputs including a data signal, D 122, a clock signal, CK 128, scan input (SI) 124, and scan enable (SE) 126. The flip flop also outputs an output signal, Q 129. According to some embodiments, the flip flop 120 is a D-type flip flop.

The circuit of FIG. 1 is not completely testable. Electronic design automatic methods and technologies such as ATPG cannot test every net for every fault. Specifically, in the example of circuit 100, ATPG can test all nets of FIG. 1A for stuck-at-1 faults. ATPG can also test all nets for stuck-at-0 faults except the net of the EN 112 of the ICG 110. Because the stuck-at-0 fault at the enable net of the ICG 110 cannot be tested, ATPG labels these faults “possibly detected” and considers the stuck-at-0 fault coverage 50%, which is a theoretical probability determined by ATPG. As such, when two faults are tested for (i.e., stuck-at-0 and stuck-at-1 faults), structured testing tools label 1.5 of 2 faults detected, and fault coverage is determined to be 75%.

With respect to transition fault testing, ATPG may detect the slow-to-rise fault of the input enable signal EN 112 of the ICG 110 but cannot detect slow-to-fall faults. The transition fault coverage for circuit 100 is thus 50%.

Even using scan based testing, in which tools (e.g., ATPG tools) initialize flip-flops to allow them to function as stimulus and observation points, the circuit 100 cannot be tested completely, and testability on the input enable signal remains incomplete (i.e., less than 100% or not substantially complete).

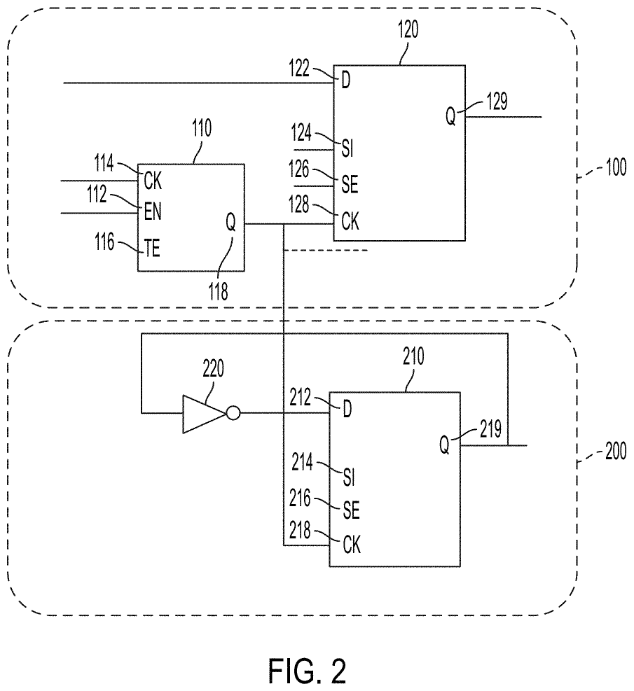

As described herein, additional circuitry 200 can be added to the circuit 100 in order to provide higher fault coverage or complete fault coverage. For example, FIG. 2 shows the exemplary circuit 100 of FIG. 1 with exemplary added circuitry 200.

According to some embodiments, the additional circuitry comprises an observation flip flop 210. The observation flip flop 210 may receive inputs such as data signal (D) 212, scan input (SI) 214, scan enable (SE) 216, and clock signal, CK 218. The observation flip flop 210 is configured to output a signal, Q 219. According to some embodiments, the additional circuit may also include an inverter, such as NOT gate 220. The NOT gate 220 may be configured to receive the output signal Q 219 as input and invert the value of the output signal Q 219 for inputting to the observation flip flop 210 as data signal input D 212.

In some embodiments, the observation flip flop 210 receives the output Q signal of the ICG 110 as input clock signal CK 218 of the observation flip flop 210. In some embodiments, the observation flip flop receives the inversion of output Q signal of the flip flop 210 as input data signal D. In some examples, the inversion may be performed using inversion circuitry (e.g., the NOT gate 220). The observation flip flop 210 does not have an impact on timing of the circuitry 100.

If the output Q 118 of the ICG is stuck at zero, the value of the flip flop at the output Q 219 will remain the same value. In the case that the enable signal EN 112 is not stuck at zero, the output of the flip flop 210 will invert itself. This can be used to ensure there is a pulse coming out of the ICG 110.

In some embodiments, ICGs can be leveraged to reduce capture power in transition fault testing. Transition delays are delays on a particular node such that the circuit does not produce an expected result within an acceptable period of time. In order to verify that the circuit can operate at its designed speed (e.g., at a maximum speed at which a circuit is to be operated or lower), the transition fault may be modeled as transition delay fault models and tested. Common transition delay fault models such as slow-to-fall and slow-to-rise are used to model a fault where, at a speed of operation (e.g., a maximum speed at which a circuit is to be operated, a designed speed of operation, etc.), the effect of a transition from a low signal to a high signal or from a high signal to a low signal, respectively, will not propagate to an output or scan flip-flop within a required time period. Such transition faults can be tested in many ways including ‘launch on capture’ and ‘launch on shift’ methods.

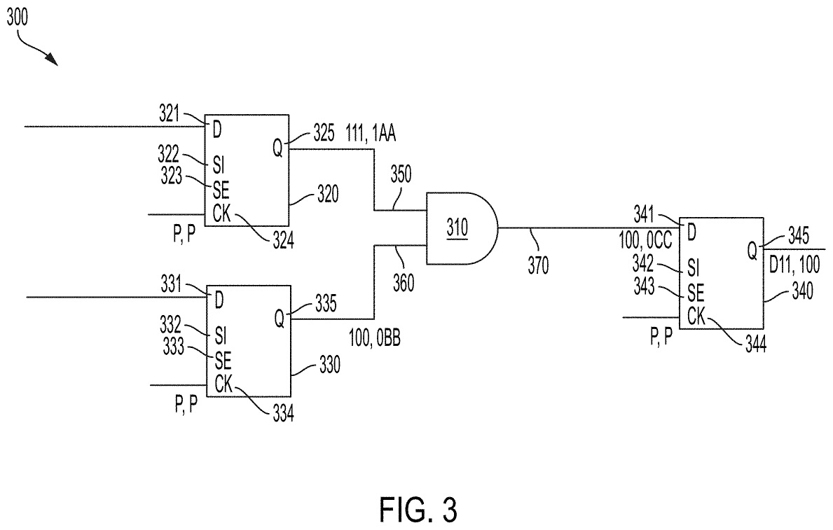

FIG. 3 is a diagram of an exemplary circuit 300 for which transition faults can be tested. Circuit 300 includes AND gate 310 having input signals 350, 360 and output signal 370. Flip flop 320 receives inputs including a data signal, D 321, a clock signal, CK 324, SI 322, and SE 323. Flip flop 320 also outputs an output signal, Q 325. Flip flops 330 and 340 similarly receive input data signals 331 and 341, clock signals 334, 344, SI 332 and 342, and SE 333 and 343 and output signals 335 and 345, respectively.

While considering the ‘launch on capture’ methodology, at least all ‘related’ flip flops are expected to pulse. For example, in the case of slow-to-fall fault testing on the input or output of an AND gate, each of the flip flops 320, 330, and 340 pulse twice during the two capture cycles, represented by ‘P, P’ of input clock signals 324, 334, and 344, resulting in a total of 6 pulses.

In the example of FIG. 3, when a first pulse is applied, a transition is initiated. In the next pulse, the observed values are captured. The logical values of the flip flops are then serially shifted out from the flip flops and analyzed. If the logical values are not equivalent to expected values, it may indicate a transition fault.

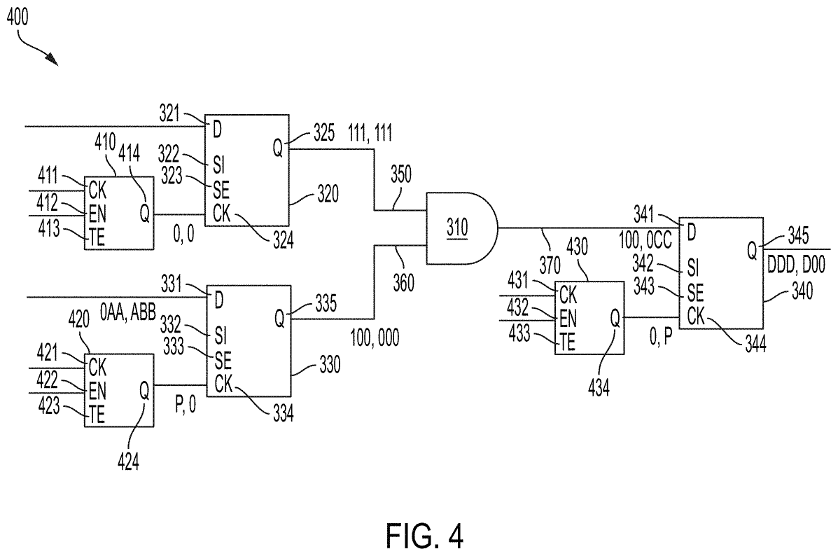

FIG. 4 is an exemplary circuit 400 which includes the exemplary circuit of FIG. 3 with added circuitry configured to reduce capture power in transition fault testing, according to some embodiments. ICGs can be added before each flip flop to control the clock signal, so that the signal is removed when not in use. For example, in FIG. 4, outputs 414, 424, and 434 of ICGs 410, 420 and 430, respectively, are added to control the clock signals 324, 334, and 344 of the flip flops 320, 330, and 340 respectively. ICGs 410, 420 and 430 may receive input signals including clock signals 411, 421, and 431, and enable signals 412, 422, and 432, respectively. The ICGs (e.g., 410, 420, and 430) may also include test enable (TE) signals (e.g., 413, 423, and 433, respectively) such that when TE is asserted, the circuit may function in a test mode.

As the ICGs can be individually controlled to pulse using the enable signals of each, rather than the 6 (i.e., 2 for each of 3 flip flop) pulses in flip flops across 2 cycles can be reduced to just 2 pulses, which may in turn reduce test power dissipated in capture mode. This test power is called capture power, which is an issue in at-speed scan testing.

According to some embodiments, flops may be grouped under different ICGs. For example, flip flops that have the maximum fan in may be chosen to be the flip flops that enable the second pulse. The controlling flip flops may be chosen to have the maximum fan out. Dormant flip flops are flip flops that have least influence, where the influence of a variable on a Boolean function is the probability that changing the value of the variable changes the value of the function.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including”, “comprising”, “having”, “containing” or “involving” and variations thereof herein, is meant to encompass the items listed thereafter and equivalents thereof as well as additional items.

The use of “coupled” or “connected” is meant to refer to circuit elements, or signals, that are either directly linked to one another or through intermediate components.

The terms “approximately”, “substantially,” and “about” may be used to mean within ±20% of a target value in some embodiments, within ±10% of a target value in some embodiments, within ±5% of a target value in some embodiments, and within ±2% of a target value in some embodiments. The terms “approximately” and “about” may include the target value.

What is claimed is:

1. A circuit for testing a fault of an enable net of an integrated clock gating (ICG) cell, the circuit comprising:
a flip flop, wherein an input clock signal of the flip flop is an output of the ICG cell, wherein the flip flop receives an inversion of an output of the flip flop as an input data signal.

2. The circuit of claim 1, wherein the inversion is performed by a NOT gate.

3. The circuit of claim 1, wherein the flip flop has no timing impact on another component that receives the output of the ICG cell.

4. The circuit of claim 1, wherein an unchanging output of the flip flop indicates a stuck-at-zero fault at an enable input of the ICG cell.

5. The circuit of claim 1, wherein a changing output of the flip flop indicates no stuck-at-zero fault at an enable input of the ICG cell.

6. A method of testing a fault of an enable net of an integrated clock gating (ICG) cell, the method comprising:
determining, based on an output of a flip flop coupled to an output of the ICG cell, whether the enable net of the ICG cell has a stuck-at-zero fault.

7. The method of claim 6, wherein determining whether the enable net of the ICG cell indicates a stuck-at-zero fault comprises determining whether the output of the flip flop exhibits pulses.

8. The method of claim 6, wherein an input clock signal of the flip flop is an output of the ICG cell.

9. The method of claim 6, wherein the flip flop receives an inversion of an output of the flip flop as an input data signal.

10. A method of performing a transition fault test, the method comprising:
asserting a first enable signal of a first integrated clock gating (ICG) cell;
pulsing, in response to asserting the first enable signal, a first pulse as a clock signal output of a first flip flop;
comparing one or more output values of the first flip flop to one or more expected values to produce a comparison; and
determining, based on the comparison, whether or not a transition fault exists.

11. The method of claim 10, further comprising:
asserting a second enable signal of a second ICG cell; and
pulsing, in response to asserting the second enable signal, a second pulse as a clock signal output of a second flip flop, wherein the second flip flop is coupled to the first flip flop.

12. The method of claim 11, wherein a clock signal input of the first flip flop is coupled to an output of the first ICG cell.

13. The method of claim 12, wherein a clock signal input of the second flip flop is coupled to an output of the second ICG cell.

14. Circuitry configured to perform a transition fault test, the circuitry comprising:
a first integrated clock gating (ICG) cell coupled to a first flip flop, wherein the first ICG cell is configured to receive a first enable signal; and
a second ICG cell coupled to a second flip flop, wherein the second ICG cell is configured to receive a second enable signal, wherein the first ICG cell and second ICG cell are individually controlled such that the first and second flip flops are operable to receive a pulse at different times.

15. The circuitry of claim 14, wherein the first flip flop is configured to pulse in response to an assertion of the first enable signal and wherein the second flip flop is configured to pulse in response to an assertion of the second enable signal.
